(19) United States
(12) Patent Application Publication
(10) Pub. No.: US 2009/0292498 A1
(43) Pub. Date: Nov. 26, 2009

(54) RESISTANCE TESTING DEVICE

(75) Inventors: LEI LI, Shenzhen City (CN); LIN-SEN DONG, Shenzhen City (CN); ZHI-QIANG JIANG, Shenzhen City (CN); PING CHEN, Shenzhen City (CN); ZHI CHENG, Shenzhen City (CN); CHANG-FA SUN, Shenzhen City (CN); CHUAN-KANG TAN, Shenzhen City (CN); LIN LI, Shenzhen City (CN); CHUN-YING WANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/467,379

(22) Filed: May 18, 2009

(30) Foreign Application Priority Data
May 23, 2008 (CN) 200810301732.9

(51) Int. Cl. G01R 27/14

(52) U.S. Cl. 702/117

(57) ABSTRACT

A resistance testing device detects resistances between testing points of an electronic element. The resistance testing device includes controls accepting input of data to the resistance testing device, a relay module, a multimeter, testing probes electrically connected to the relay module, a testing platform including a base and a probe mounting board, a driving assembly mounted on the base and moving the probe mounting board relative to the electronic device, a display, and a central processing assembly mounted within the base. The relay module controls the testing probes and implements the multimeter to detect resistances between the testing points. The base seats the electronic element, the probe mounting board fixes the testing probes, and the probe mounting board is adjustably mounted above the base. The central processing assembly includes a central processing unit. The central processing unit is respectively and electronically connected to the controls, driving assembly, display and the relay module. The central processing unit provides input of data and implements the driving assembly, display, relay module and the multimeter, and analyzes testing results, and the display shows input data and testing results.

### BACKGROUND

1. Technical Field

The present disclosure relates to resistance testing devices and, particularly, to a device capable of testing multiple resistances.

2. Description of Related Art

Resistance testing is required for electronic elements before assembly with another electronic element. Plans of the electronic element define a plurality of testing points, one of which is designated as a common point providing reference from which other testing points can be tested.

It is necessary to test the resistance values between the other testing points and the common point using a multimeter or impedance instrument, and record the resistance values. When the testing is finished, the resistance values are input into a computer to determine compliance with specific requirements.

The testing method described, however, is complex, requiring labor and affecting testing efficiency.

Therefore, there is room for improvement within the art.

### BRIEF DESCRIPTION OF THE DRAWINGS

Many aspects of the resistance testing device can be better understood with reference to the following drawings. These drawings are not necessarily drawn to scale, the emphasis instead being placed upon clearly illustrating the principles of the present resistance testing device. Moreover, in the drawings like reference numerals designate corresponding sections throughout the views.

FIG. 1 is a schematic showing a resistance testing device in accordance with the disclosure.

FIG. 2 is an isometric, exploded view of the resistance testing device of FIG. 1.

FIG. 3 is an isometric, assembled view of the resistance testing device of FIG. 1.

FIG. 4 shows the working condition of the resistance testing device of FIG. 1.

FIG. 5 shows another working condition of the resistance testing device of FIG. 1.

### DETAILED DESCRIPTION

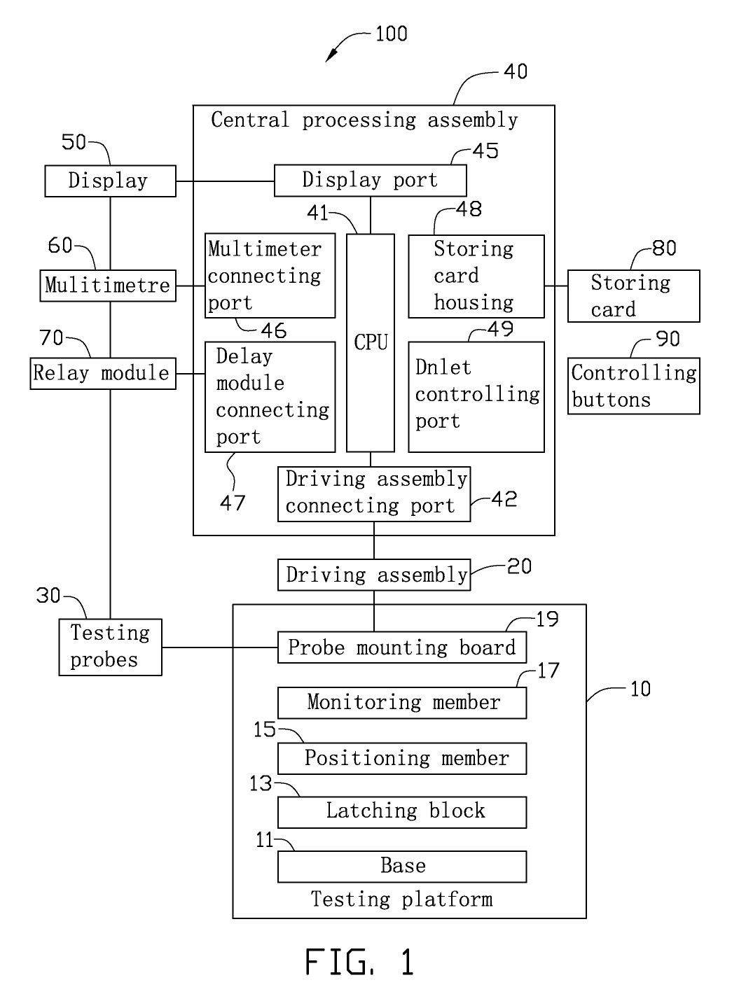

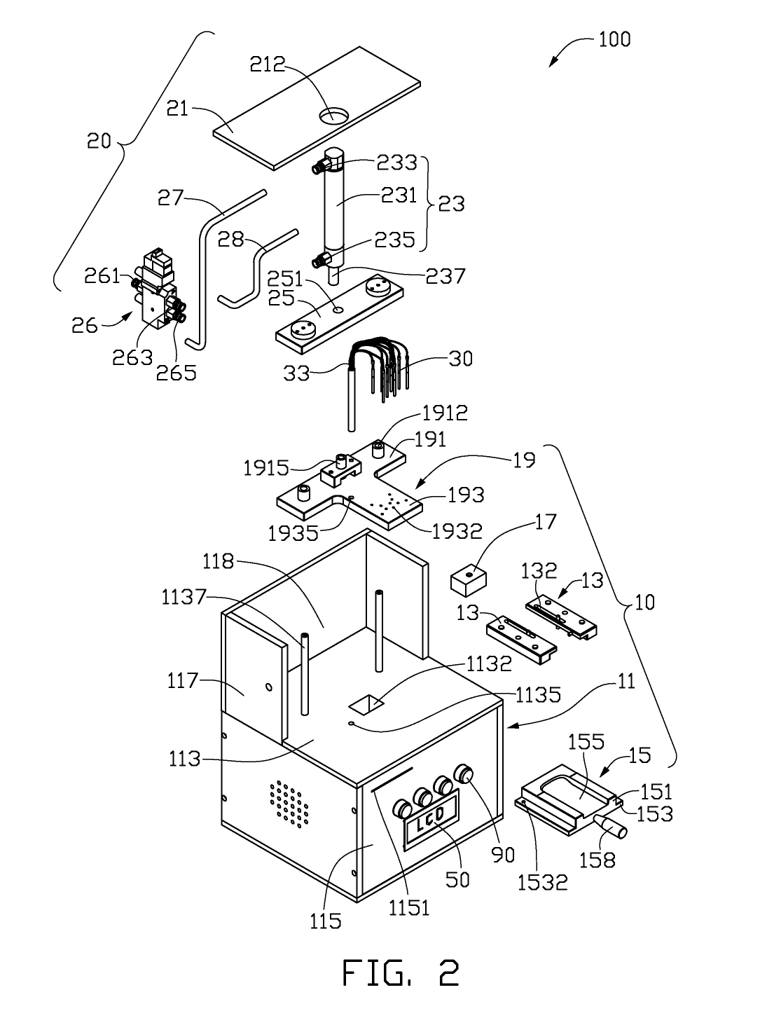

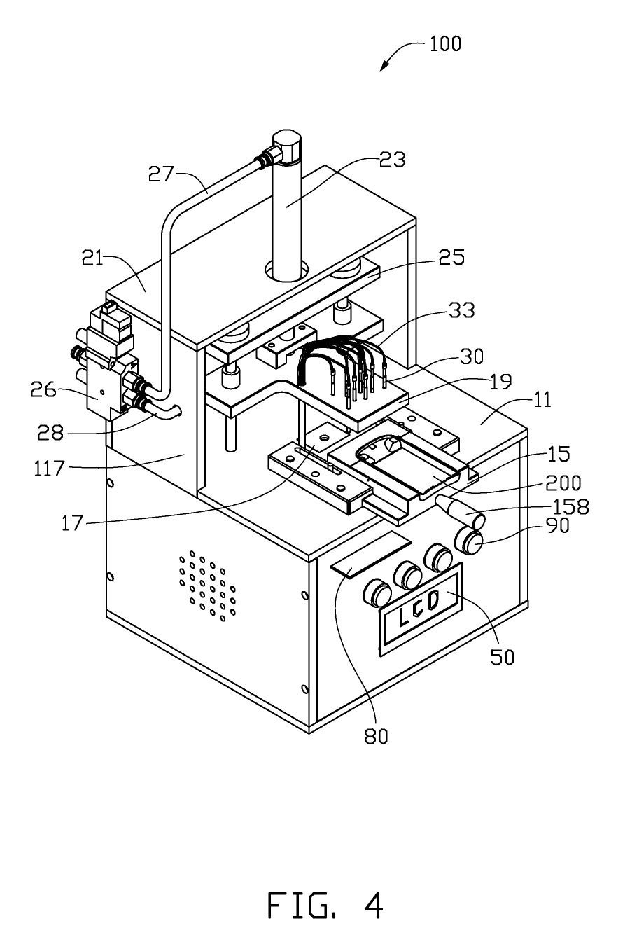

FIG. 2 shows an exemplary resistance testing device 100 used to detect resistances of an electronic element 200 (FIG. 4) with testing points (not shown) thereon. Referring to FIG. 1 to FIG. 3, a resistance testing device 100 includes a testing platform 10, a driving assembly 20, testing probes 30, a central processing assembly 40, a display 50, a multimeter 60, a relay module 70, a storage card 80 and controls 90. The driving assembly 20 is mounted on the testing platform 10. The central processing assembly 40, the multimeter 60, the relay module 70, and the storage card 80 are positioned within the testing platform 10. The display 50 and the controls 90 are disposed on the testing platform 10.

Referring to FIGS. 2-4, the testing platform 10 seats the electronic element 200 and includes a base 11, two latching blocks 13, a positioning member 15, a monitoring member 17 and a probe mounting board 19.

The base 11 includes a top board 113, an operating board 115, and a protecting board 117. The top board 113 defines a mounting hole 1132 and a first connecting hole 1135 through in a center thereof. The top board 113 further includes two guide columns 1137 symmetrically protruding therefrom, adjacent to the mounting hole 1132 and the first connecting hole 1135. The operating board 115 defines a card slot 1151 receiving a storage card 80 (FIG. 4) therein. The controls 90 and the display 50 are disposed on the operating board 115. The protecting board 117 may be generally “U”-shaped and fastened to the top board 113, such as, with fasteners, adjacent to the guide columns 1137. The protecting board 117 and the top board 113 cooperatively enclose a receiving space 118. The receiving space 118 receives the two guide columns 1137 therein.

Each latching block 13 has an “L”-shaped cross-section, defining a sliding slot 132. The two latching blocks 13 are mounted on the top board 113, with the sliding slot 132 extending parallel to the top board 113. The two latching blocks 13 are symmetrically disposed on both sides of the mounting hole 1132. The two latching blocks 13 and the top board 113 cooperatively enclose a mounting space 119, for receiving the positioning member 15.

The positioning member 15 can be received in the mounting space 119. The positioning member 15 includes a main portion 151, two sliding blocks 153, a positioning portion 155 and a contact rod 158. A fixing hole 1532 is defined in a distal end of each sliding block 153. The fixing hole 1532 receives a fastener (not labelled) therein, slidably received in the sliding slot 132. The positioning portion 155 is a generally rectangular concave and is defined in the main portion 151. The positioning portion 155 is configured to support the electronic element 200. The contact rod 158 is fastened to the main portion 151. The positioning member 15 is sandwiched between the two latching blocks 13 with the sliding cooperation of the two sliding blocks 153 and the mounting space 119.

The monitoring member 17 is an optical fiber sensor. The monitoring member 17 is mounted on the mounting hole 1132. The monitoring member 17 is electrically connected to the central processing assembly 40 to monitor a position of the electronic element 200 and send the position signal to the central processing assembly 40.

The probe mounting board 19 can be T-shaped, including a connecting portion 191 and a mounting portion 193. The connecting portion 191 includes two hollow poles 1912, corresponding to the guide columns 1137. The guide columns 1137 are respectively and slidably received in the hollow poles 1912. The connecting portion 191 further includes a fastening block 1915 at a center thereof receiving the probe mounting board 19 to the driving assembly 20. The mounting portion 193 defines through probe mounting holes 1932 and a second connecting hole 1935. The second connecting hole 1935 corresponds to the first connecting hole 1135, with both allowing passage of the testing probes 30 therethrough.

The driving assembly 20 is mounted on the top board 113 of the testing platform 10 and received in the receiving space 118. The driving assembly 20 is fixed to the connecting portion 191 and drives the testing probes 30 up and down along the guide columns 1137. In this embodiment, the driving assembly 20 includes a mounting board 21, a pneumatic cylinder 23, a fixing board 25, an electromagnetic valve 26, an inlet air pipe 27 and an outlet air pipe 28. The mounting board 21 mounted on the protecting board 117 and covering the receiving space 118 and the two guide columns 1137. The mounting board 21 defines a hole 212, through which the pneumatic cylinder 23 passes. The pneumatic cylinder 23, including a pneumatic cylinder body 231, an inlet air pipe mounting portion 233, an outlet air pipe mounting portion 235 and a piston 237 slidably mounted in the pneumatic cylinder body 231. The fixing board 25, defining a mounting hole 251 at a center through which the piston 237 passes. The fixing board 25 is fixedly mounted on the two free ends of the two guide columns 1137. The electromagnetic valve 26 is fastened to a protecting board 117 and controls the pneumatic cylinder 23. The electromagnetic valve 26 includes an air source inlet end 261, and an inlet air pipe connecting end 263, an outlet air pipe connecting end 265. One end of the inlet air pipe 27 is connected to the inlet air pipe connecting end 263, and the other is connected to the inlet air pipe mounting portion 233 of the pneumatic cylinder 23. One end of the outlet air pipe 28 is connected to the outlet valve connecting end 265, and the other is connected to the outlet air pipe mounting portion 235 of the pneumatic cylinder 23.

The testing probes 30 are correspondingly mounted on the probe mounting hole 1932 of the mounting end 193. One end of each testing probe 30 passes through the probe mounting board 19, exposing under the probe mounting board 19 and facing the mounting space 119. The other end of each testing probe 30 is connected to the relay module 70 through the first connecting hole 1135 and the second connecting hole 1935.

The central processing assembly 40 is mounted within the base 11. The central processing assembly 40 includes a central processing unit (CPU) 41, a driving assembly connecting port 42, a display connecting port 45, a multimeter connecting port 46, a relay module connecting port 47, a storage card housing 48, and an inlet controlling port 49. The driving assembly connecting port 42, the display port 45, the multimeter connecting port 46, the relay module connecting port 47, the storage card housing 48, and the inlet controlling port 49 are all electrically connected to the CPU 41 and respectively and correspondingly connected to the driving assembly 20, the display 50, the multimeter 60, the relay module 70, the storage card 80, and the controls 90. The controls 90 provide input of data to the CPU 41, such as startup and result processing.

The multimeter 60 is mounted within the base 11, with one end connected to the multimeter connecting port 46 and the other to the relay module 70.

The relay module 70 is mounted within the base 11, with one end connected to the relay module controlling port 47 and the other connected to the multimeter 60 and the testing probes 30.

The storage card 80 is detachably inserted into the storage card housing 48 via the card slot 1151.

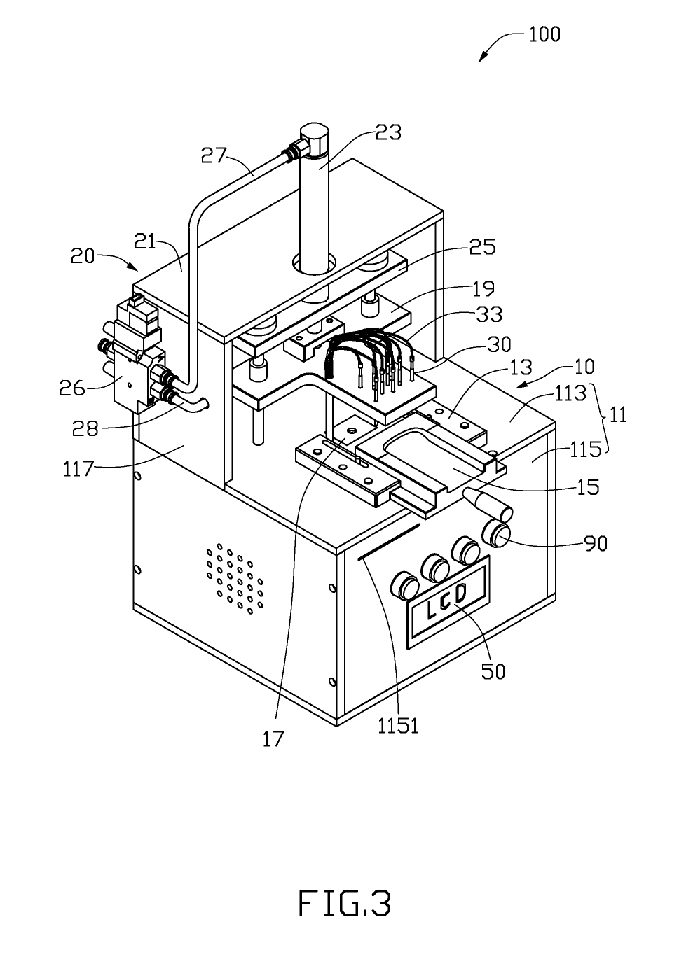

Referring to FIG. 3, in assembly, the positioning member 15 is mounted in the mounting space 119. Two fasteners are fastened into the fixing holes 1532 of the positioning member 15 through the sliding slots 132, thus allowing the positioning member 15 to slide along the sliding slots 132. The probe mounting board 19 is slidably mounted on the two guide columns 1137, with one end of each testing probe 30 facing the positioning member 15, and the other end connected to the relay module 70 through the second connecting hole 1935 and the first connecting hole 1135. The pneumatic cylinder body 231 of the pneumatic cylinder 23 is mounted on the fixing board 25, with the piston 237 connected to the fastening block 1915 of the probe mounting board 19 through the mounting hole 251. Thus, the probe mounting board 19 can be driven up and down by the pneumatic cylinder 23. The inlet air pipe mounting portion 233 of the pneumatic cylinder 23 communicates with the inlet air pipe connecting end 263 by the inlet air pipe 27, and the outlet air pipe mounting portion 235 of the pneumatic cylinder 23 communicates with the outlet air pipe connecting end 265 by the outlet air pipe 28. The central processing assembly 40, the multimeter 60 and the relay module 70 are mounted within the base 11. The driving assembly 20, the display 50, the multimeter 60, the relay module 70, the storage card 80, and the controls 90 are respectively and correspondingly connected to the driving assembly connecting port 42, the display port 45, the multimeter connecting port 46, the relay module connecting port 47, the storage card housing 48, and the inlet controlling port 49.

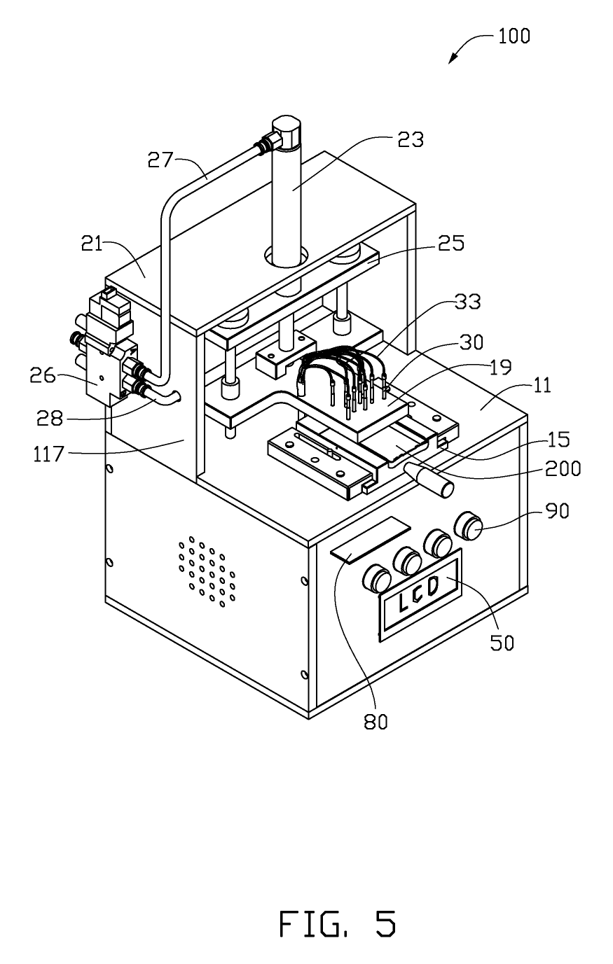

Referring to FIGS. 4 and 5, in use, the storage card 80 is inserted into the card slot 1151. Electronic element 200 is fixed in the positioning portion 155 of the positioning member 15. The positioning member 15 is moved towards the sliding columns 1137 along the sliding slot 132 until the electronic element 200 is located under the testing probes 30. Monitoring member 17 begins determining the position of the electronic element 200. If the position thereof is acceptable, the driving assembly 20 moves the probe mounting board 19 downward until testing probes 30 contact the testing points of the electronic element 200. Resistances among the testing points are detected by the multimeter 60. The central processing assembly 40 stores the acquired data on the storage card 80 for comparison with prestored standard data and subsequent determination of compliance with requirements.

Alternatively, the monitoring member 17 can be a photoinduction switch.

Alternatively, the driving assembly 20 can be a stepped motor or other.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of sections within the principles of the disclosure to the full extent indicated by the broad general meaning of the terms, in which the appended claims are expressed.

What is claimed is:

1. A resistance testing device for determining resistances between testing points of an electronic element, the device comprising:
controls accepting input of data to the resistance testing device;
a relay module;
a multimeter;
testing probes electrically connected to the relay module, the relay module controlling the testing probes and directing the multimeter to detect resistances between the testing points;
a testing platform including a base and a probe mounting board, the base seating the electronic element, the probe mounting board being fixing the testing probes, and the probe mounting board adjustably mounted above the base;
a driving assembly mounted on the base and moving the probe mounting board relative to the electronic device;
a display; and
a central processing assembly mounted within the base, the central processing assembly comprising a central processing unit electronically connected to the controls, the driving assembly, the display and the relay module, receiving data and implementing the driving assembly, the display, the relay module and the multimeter, and analyzing testing results, wherein the display displays input data and testing results.

2. The resistance testing device as claimed in claim 1, wherein the central processing assembly further comprises a driving assembly connecting port, a display connecting port, a multimeter connecting port, a relay module connecting port, and an inlet controlling port, the driving assembly connecting port, the display port, the multimeter connecting port, the relay module connecting port, and the inlet controlling port all electrically connected to the central processing unit and respectively and correspondingly connected to the driving assembly, the display, the multimeter, the relay module, and the controls.

3. The resistance testing device as claimed in claim 2, wherein the base comprises a top board, an operating board, and a protecting board, the top board including two guide columns symmetrically protruding therefrom, the controls and the display disposed on the operating board, the protecting board fixed to the top board adjacent to the guide columns, wherein the protecting board and the top board cooperatively enclose a receiving space receiving the driving assembly and the two guide columns therein.

4. The resistance testing device as claimed in claim 3, wherein the testing platform further comprises two latching blocks and a positioning member, the latching blocks having an “L”-shaped cross-section and mounted on the top board, and the two latching blocks and the top board cooperatively enclosing a mounting space receiving the positioning member.

5. The resistance testing device as claimed in claim 4, wherein each latching block defines a sliding slot and the positioning member correspondingly defines a mounting hole configured to fix a fastener therein, wherein the fastener can be slidably received in the sliding slot.

6. The resistance testing device as claimed in claim 5, wherein the positioning member further comprises a positioning portion and a contact rod, the positioning portion fixing the electronic element and the contact rod allowing manipulation of the positioning member.

7. The resistance testing device as claimed in claim 3, wherein the probe mounting board comprises a connecting portion and a mounting portion, the connecting portion includes two hollow poles corresponding to the guide columns, wherein the guide columns are respectively and slidably received in the hollow poles, and the connecting portion further includes a fastening block at a center mounting the probe mounting board to the driving assembly.

8. The resistance testing device as claimed in claim 7, wherein the mounting portion defines through probe mounting holes allowing passage of the testing probes therethrough.

9. The resistance testing device as claimed in claim 4, wherein the top board defines a mounting hole at a center thereof, between the two latching blocks, and the testing platform further comprises a monitoring member received in the mounting hole and electrically connected to the central processing unit, wherein the monitoring member detects the position of the electronic element.

10. The resistance testing device as claimed in claim 1, wherein the resistance testing device further comprises a storage card, the central processing assembly further includes a storage card housing electrically connected to the central processing assembly, and the operating board defines a card slot corresponding to and receiving the storage card.

11. A resistance testing device for testing resistances between testing points of an electronic element comprising:
controls accepting input of data to the resistance testing device;
a relay module;
a multimeter;
testing probes electrically connected to the relay module, the relay module controlling the testing probes and causing the multimeter to detect resistances between the testing points;
a testing platform including a base and a probe mounting board, the base seating the electronic element, the probe mounting board fixing the testing probes, and the probe mounting board adjustably mounted above the base;
a driving assembly mounted on the base and moving the probe mounting board relative to the electronic device; and
a central processing assembly mounted within the base and including a central processing unit electronically connected to the controls, driving assembly, the display and the relay module, wherein the central processing unit receives input data and implementing the driving assembly, relay module and the multimeter and analyzing testing results.

12. The resistance testing device as claimed in claim 11, further comprising a display to which the central processing unit is electronically connected, displaying input data and testing results.

13. The resistance testing device as claimed in claim 12, the central processing assembly further comprising a driving assembly connecting port, a display connecting port, a multimeter connecting port, a relay module connecting port, and an inlet controlling port, the driving assembly connecting port, the display port, the multimeter connecting port, the relay module connecting port, and the inlet controlling port all electrically connected to the central processing unit and respectively and correspondingly to the driving assembly, the display, the multimeter, the relay module, and the controls.

14. The resistance testing device as claimed in claim 13, wherein the base comprises a top board, an operating board, and a protecting board, the top board including two guide columns symmetrically protruding therefrom, the controls and the display disposed on the operating board, the protecting board fixed to the top board adjacent to the guide columns, and the protecting board and the top board cooperatively enclose a receiving space receiving the driving assembly and the two guide columns therein.

15. A resistance testing device for detecting resistances between testing points of an electronic element comprising:
a relay module;
a multimeter;
testing probes electrically connected to the relay module, the relay module moving the testing probes and causing the multimeter to detect resistances between the testing points;
a testing platform comprising a base and a probe mounting board, the base seating the electronic element, the probe mounting board fixing the testing probes, and the probe mounting board adjustably mounted above the base;
a driving assembly mounted on the base and moving the probe mounting board relative to the electronic device; and
a central processing assembly mounted within the base and comprising a central processing unit respectively and electronically connected to the driving assembly, and the relay module, starting the driving assembly, the relay module and the multimeter, and analyzing testing results.

16. The resistance testing device as claimed in claim 15, further comprising controls accepting input of data to the resistance testing device, the central processing unit electronically connected to the controls.

17. The resistance testing device as claimed in claim 16, further comprising a display to which the central processing unit is electronically connected, displaying input data and testing results.
